(19) United States
(12) Patent Application Publication
(10) Pub. No.: US 2003/0215962 A1
(43) Pub. Date: Nov. 20, 2003

(54) Integration of multiple processes within a single chamber

(75) Inventors: Gilbert Hausmann, Felton, CA (US); Mohamed Al-Sharif, San Jose, CA (US)

Correspondence Address: APPLIED MATERIALS, INC., 2881 SCOTT BLVD. M/S 2061, SANTA CLARA, CA, 95050, US

(73) Assignee: APPLIED MATERIALS, INC., Santa Clara, CA

(21) Appl. No.: 10/146,324

(22) Filed: May 14, 2002

(51) Int. Cl. H01L 21/00

(52) U.S. Cl. 438/7

(57) ABSTRACT

A method for forming a semiconductor device includes placing a semiconductor substrate on a top surface of a pedestal provided within a process chamber. A patterned photoresist layer provided over the substrate is stripped within the process chamber while maintaining the substrate at a first temperature. The patterned photoresist layer overlies a patterned insulating layer. The first temperature of the semiconductor substrate provided within the chamber is raised to a second temperature to remove volatile species from the patterned insulating layer.

### BACKGROUND OF THE INVENTION

The present invention relates to a method and apparatus for forming a patterned layer of material on a substrate for fabricating semiconductor devices.

Forming a patterned layer of material on a semiconductor substrate involves performing a plurality of steps in a plurality of process chambers. Currently, the process begins with deposition of an etch layer, i.e., a layer to be etched, onto a substrate in a first process chamber. The substrate is removed from the first chamber and inserted into a second chamber to deposit a photoresist layer. Once the photoresist layer has been deposited, the substrate is transported to a third chamber and the photoresist layer is patterned to expose portions of the etch layer. In a fourth chamber, the exposed portions of the etch layer is etched to expose portions of the substrate, thereby defining one or more trenches within the etch layer. Afterwards, the photoresist layer is stripped and removed from the etch layer in a fifth chamber. This stripping step may leave undesirable residues on the etch layer and substrate, which are removed later by performing an ashing step. The ashing step may be performed within the fifth chamber or in a separate chamber. After the ashing step, the substrate is transported to a sixth chamber to perform wet clean step to further remove the residues on the etch layer or substrate. Subsequently, the substrate is placed in a seventh chamber to perform a degas step to remove volatile species from the etch layer. The degas step generally involves heating the substrate with heat lamps. Finally, the substrate is placed in an eighth chamber to perform a sputtering step to round the corners of the trench and/or to remove a native oxide layer on the exposed portions of the substrate.

As seen from the above, forming a single pattern layer involves use of at least eight different chambers under the conventional method. Each significant fabrication step is performed in a dedicated chamber that is specifically configured for that particular step to provide optimum process conditions. In addition, some of the above steps cannot be combined in a single chamber under conventional methods. For example, the degas step is performed in a chamber having heating lamps. These lamps cannot be integrated to an ashing or etching chamber because of the harsh process conditions within such a chamber. However, use of so many chambers increases equipment costs and also reduce throughput since the substrate is transported to multiple chambers.

### SUMMARY OF THE INVENTION

In one embodiment, a method for forming a semiconductor device includes placing a semiconductor substrate on a top surface of a pedestal provided within a process chamber. A patterned photoresist layer provided over the substrate is stripped within the process chamber while maintaining the substrate at a first temperature. The patterned photoresist layer overlies a patterned insulating layer. The first temperature of the semiconductor substrate provided within the chamber is raised to a second temperature to remove volatile species from the patterned insulating layer.

### BRIEF DESCRIPTION OF THE DRAWINGS

FIG. 1 illustrates a simplified process chamber that incorporates the use of a high temperature electrostatic chuck according one embodiment of the present invention.

FIG. 2 illustrates a simplified cluster tool substrate processing system that may be used to practice according to an embodiment of the present invention.

FIG. 3A-4E illustrate various stages of a semiconductor fabrication process according to one embodiment of the present invention.

FIG. 5 illustrate a curve of temperature versus time for a substrate fabricated according to one embodiment of the present invention.

### DESCRIPTION OF THE SPECIFIC EMBODIMENTS

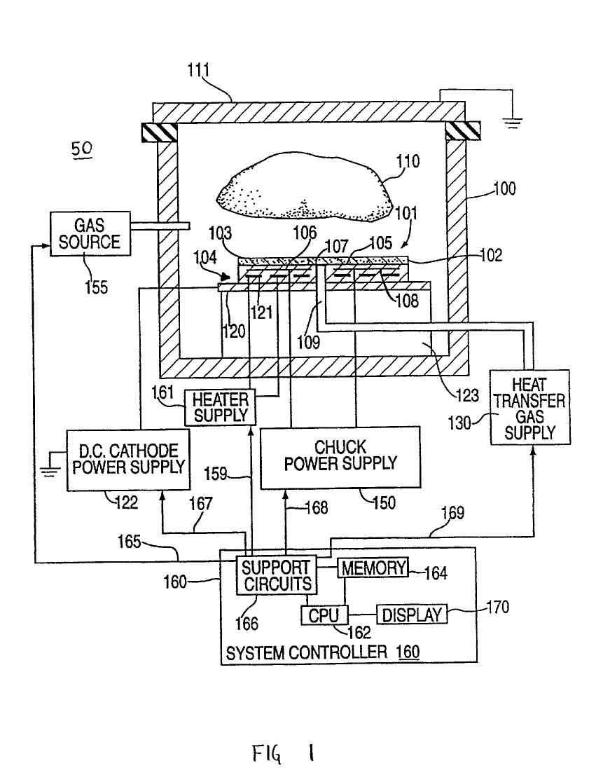

FIG. 1 illustrates a cross-sectional view of an embodiment of a process chamber 100 of a plasma processing system 50 that may be used to practice the present invention. The process chamber 100 has a high temperature electrostatic chuck 104. A wafer 102 is supported in the chamber 100 upon a pedestal 101 that contains a bipolar electrostatic chuck 104 and a cathode electrode 120. The chuck 104 has a pair of electrodes 106 and 108 embedded within the chuck body 107 made of a dielectric such as polyimide, aluminum nitride, boron nitride, alumina, and the like. A voltage, from a chuck power supply 150, applied to the electrodes 106 and 108, holds the wafer 102 against the chuck 104 by electrostatic force.

The wafer is heated by resistive heater 121. Resistive heater 121 is controlled by heater power supply 161. The resistive heater is capable of heating the wafer to a temperature of about 350° C. or more, preferably about 450° C. Additionally, the temperature of the wafer is controlled by applying a heat transfer medium (a gas such as helium) between the wafer 102 and the chuck 104 to fill the vacuum within the interstitial spaces beneath the wafer. A heat transfer medium, generally known as backside gas, promotes uniform heat transfer between the pedestal assembly and the wafer. The wafer has to be chucked in order to maintain a pocket of backside gas between the wafer and the chuck and to prevent the wafer from floating off the chuck. Also, any chucking voltage may be used with the method of the present invention, which includes both DC and AC.

A heat transfer gas supply 130 provides backside gas for transferring heat from the chuck 104 to the wafer 102. The backside gas flows through a passageway 109 in the chuck body 107 to support the surface 105 and disperses between the wafer and support surface to improve heat transfer between the pedestal and wafer.

An anode electrode 111 is disposed above the wafer 102 and the chuck 104. The cathode electrode 102 is disposed immediately below the chuck 104 and supports the chuck 104 in the chamber 100. Alternatively, the cathode electrode may be formed by additionally or alternatively biasing the walls of the chamber 100 relative to the anode electrode 111. A cathode power supply 122 provides voltage to the cathode electrode 120.

In one implementation, during plasma processing of the wafer, a gas such as argon, helium, hydrogen, or a combination thereof is supplied to the chamber, from a gas source 155. Once the chamber has an appropriate gas pressure, energy from a DC voltage supplied to the chamber by the cathode power supply 122 ignites and sustains the plasma 110.

A system controller 160 includes hardware that provides the necessary signals to initiate, regulate, and terminate the processes occurring in the preclean chamber 100. The system controller 160 includes a programmable central processing unit (CPU) 162 that is operable with a memory 164 (e.g., RAM, ROM, hard disk and/or removable storage) and well-known support circuits 166 such as power supplies, clocks, cache, and the like. By executing software stored in the memory 164, the system controller 160 produces control outputs 159, 165, 167, and 169 that respectively provide signals for controlling the heater power supply 161, the gas source 155, the cathode power supply 122, the chuck power supply 150, and the heat transfer gas supply 130. The system controller 160 also includes hardware for monitoring the processes through sensors (not shown) in the chamber 100. Such sensors measure system parameters such as temperature, chamber atmospheric pressure, plasma content, voltage and current. Furthermore, the system controller 160 includes at least one display device 170 that displays information in a form that can be readily understood by a human operator. The display device 170 is, for example, a graphical display that portrays system parameters and control icons upon a “touch screen” or light pen based interface.

One or more steps in the method of the present invention could be implemented by a suitable computer program running on the CPU 162 of the system controller 160. The CPU 162 is a general purpose computer that performs a specific function when executing programs. Embodiments of the invention described herein are implemented in software and executed upon a general purpose computer. Alternatively, some or all of these embodiments may be implemented using hardware such as an application specific integrated circuit (ASIC) or other hardware circuitry. As such, the invention should be understood as being able to be implemented, in whole or in part, in software, hardware or both.

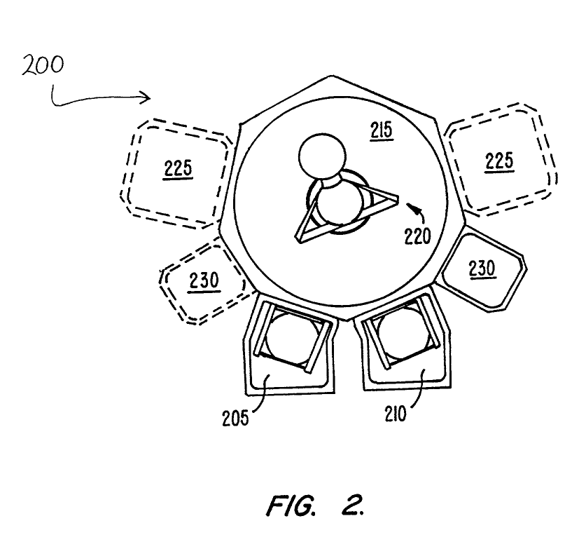

FIG. 2 illustrates an embodiment of a simplified cluster tool 200, whereupon the process chamber 100 may be incorporated to practice an embodiment of the present invention. The cluster tool system 200 includes vacuum load-lock chambers 205 and 210. The load-lock chambers 205 and 210 maintain vacuum conditions within transfer the chamber 215 while substrates enter and exit the cluster tool 200. A robot 220 serves substrates from/to the load-lock chambers 205 and 210 to substrate processing chambers 225 and 230. In one implementation, the process chamber 100 is incorporated into the cluster tool as the chamber 225.

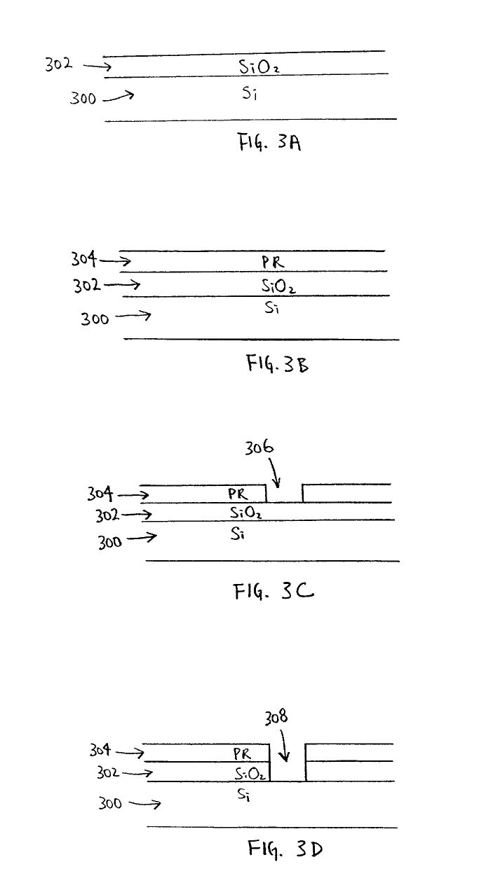

FIGS. 3A-3D depict a process flow of fabricating a semiconductor device, where each step is generally performed in a separate chamber. Referring to FIG. 3A, a substrate 300 is inserted into a first chamber (not shown). A dielectric layer 302, e.g., SiO₂, is formed over the substrate using a conventional method. The substrate is removed from the first chamber and inserted into a second chamber (not shown) to prepare the substrate for the next processing step (FIG. 3B). A photoresist layer 304 is provided over the dielectric layer 302. The photoresist layer may be of positive or negative photoresist material. The substrate is removed from the second chamber and provided in a third chamber to pattern the photoresist layer 304. Accordingly, relevant portions of the photoresist layer 304 are exposed to light. An opening 306 is formed on the photoresist layer 304. Thereafter, the substrate is provided in a fourth chamber (not shown) to etch the exposed portion of the dielectric layer 302. As a result, an opening 308 is formed on the dielectric layer to expose a portion of the substrate 300.

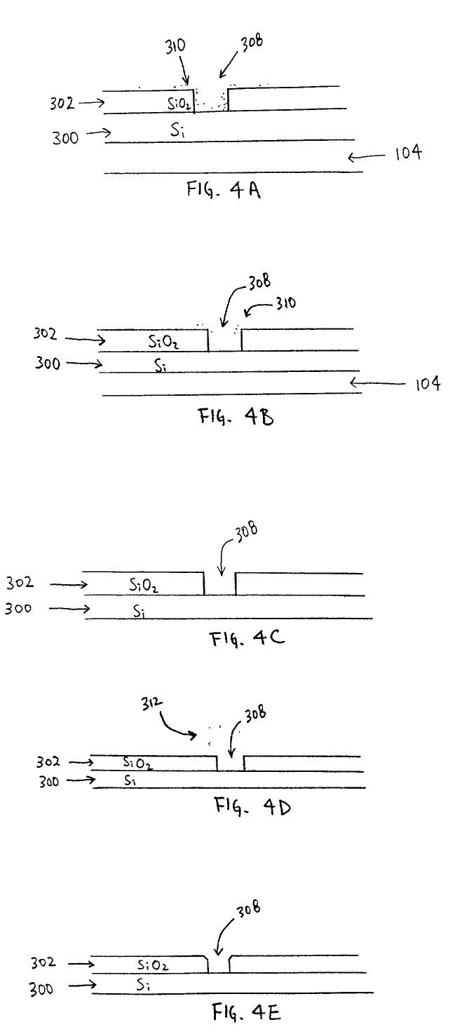

FIGS. 4A-4E depict a process flow of fabricating a semiconductor device, according to one embodiment of the present invention. After the opening 308 has been formed, the substrate 300 is provided in the process chamber 100 to perform a plurality of steps within that chamber. The substrate is placed on the chuck 104, and the photoresist layer 304 is stripped from the dielectric layer (FIG. 4A). The stripping step leaves residues 308, e.g., polymer, on the dielectric layer and within the opening 308. These residues are removed by performing an ashing step within the chamber 100. The ashing step typically involves flowing oxygen gas into the chamber and igniting plasma therein to remove the residues.

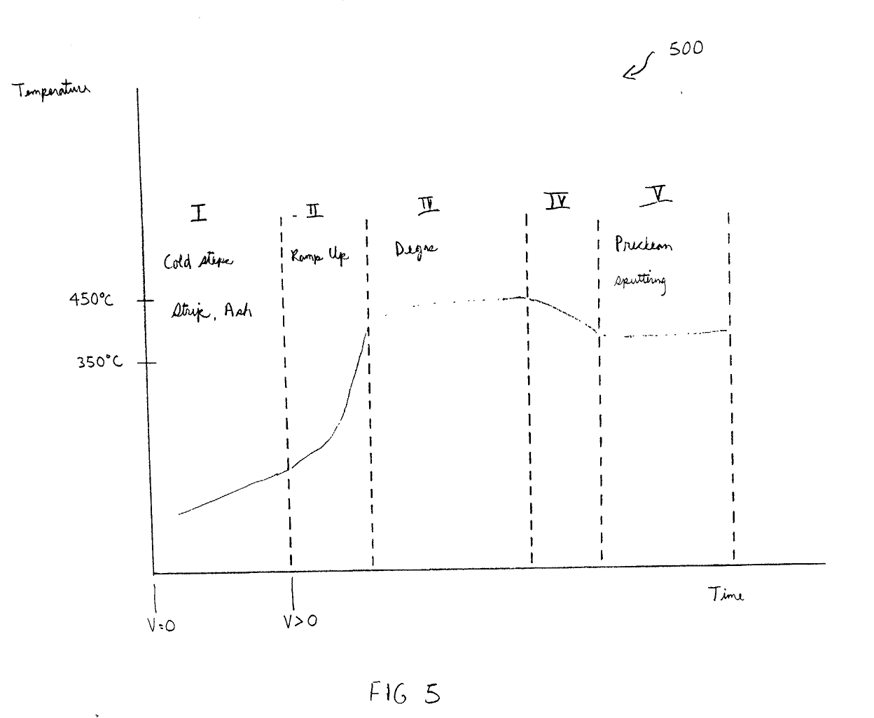

During the above steps, the substrate is kept below a first temperature level, e.g., 350° C., as shown in a graph 500 (FIG. 5). The graph 500 plots changes in the temperature of the substrate 300 over time, showing five different temperature zones for the substrate. In one implementation, the substrate temperature is at 100° C. or less when it is placed onto the chuck 104. The temperature of the chuck is at about 350° C. to about 500° C. Consequently, the substrate temperature is increased from first temperature to second temperature during the course of the above steps. In one implementation, the first temperature is between about 100° C. and about 300° C. In another implementation, the temperature is between about 200° C. and about 250° C. Additionally or alternatively, no voltage is applied to the chuck electrodes 106 and 108, and the backside gas is kept turned off to prevent the substrate from heating too fast during these steps. Therefore, as seen from the above, the stripping and ashing steps are performed in Zone I.

Referring to FIG. 4C, if the residues are not removed satisfactorily with the ashing step, the substrate 300 may be exposed to a fluorine clean step to further clean the substrate. In some cases, the residues 310 may include SiO₂ residues that would be difficult to remove with the ashing process. They are more easily removed with the fluorine clean step, which uses fluorine-containing gas. In one implementation, the fluorine clean step involves flowing about 3 sccm of NF₃ and about 47 sccm of He into the chamber 100, for about 27 seconds. The substrate temperature is kept between about 100° C. to about 275° C., preferably between about 200° C. and about 250° C., during this cleaning step. As with the stripping and ashing steps, the cleaning step is performed in Zone 1. In other implementations, other types of fluorine based gas may be flowed into the chamber to perform the cleaning step, e.g., SF₆ and CF₄. Yet in other implementations, the substrate may be removed from the chamber 100 to perform a wet clean process to remove the SiO₂ residues.

After the cleaning step has been performed, a substrate temperature ramp-up step is performed to prepare the substrate for a degas step. The ramp-up step involves applying a chucking voltage, e.g., about 400 watt, to the chuck electrodes 106 and 108 to firmly hold the substrate to the chuck. Next, backside gas is flowed between the substrate and the chuck to increase the substrate temperature more rapidly and uniformly at the same time. This step is represented on the graph 500 as Zone II and performed for about 25-30 seconds or until the substrate temperature reaches an appropriate level, e.g., 350° C., to degas the substrate. In one implementation, the degas step (Zone III) is performed between about 275° C. and about 500° C. In another implementation, the degas step is performed between about 350° C. and about 450° C., preferably between about 350° C. and about 400° C. The degas step is performed for about 30 seconds in one implementation. The degas step is generally performed to remove moisture and volatile species 312 from the substrate and dielectric layer 302. Although higher temperatures are more effective in removing these volatile species, they also increase the likelihood of damaging the dielectric layer 302. Therefore, an appropriate degas temperature for a particular process needs to be selected upon careful consideration of these trade-offs. In other implementations, the ramp-up and degas steps are performed immediately after the ashing step if the cleaning step is not performed.

After the degas step, the substrate temperature is lowered to perform a sputtering step to round the corners of the opening 308 or remove a native oxide layer (not shown) overlying the exposed surface of the substrate 300. Generally, the backside gas and chucking voltage are turned off to lower the substrate temperature somewhat, as shown by Zone IV. Thereafter, the sputtering step is performed in Zone V.

The above embodiments or implementations of the present invention enables the stripping, ashing, degas, and preclean steps to be performed within a single chamber. It has been a conventional wisdom that etch or ashing steps need to be performed in a separate chamber from the degas step because the degas chamber uses lamps to heat the substrate to remove volatile species therefrom. The lamps would be damaged if the degas chamber is used perform the etch or ashing steps. The present invention teaches using a chamber without a lamp to perform the degas step, thereby enabling the etching and/or ashing steps to be performed within the same chamber as that used to perform the degas step.

As understood by those of skill in the art, the present invention may be embodied in other specific forms without departing from the essential characteristics thereof Accordingly, the foregoing description is intended to be illustrative, but not limiting, of the scope of the invention which is set forth in the following claims.

What is claimed is:

1. A method of stripping photoresist and removing residues from a semiconductor wafer, the method comprising:
stripping a patterned photoresist layer overlying a semiconductor wafer while maintaining the wafer at a first temperature, the wafer being positioned upon a pedestal within a process chamber, the patterned photoresist layer overlying a patterned insulating layer, the patterned layers defining a trench; and
raising the first temperature of the wafer positioned upon the pedestal within the chamber to a second temperature to remove volatile species from the patterned insulating layer.

2. The method of claim 1, further comprising:
etching the insulating layer overlying the wafer to pattern the insulating layer.

3. The method of claim 2, wherein the trench has a plurality of corners, the method further comprising:
lowering the second temperature of the wafer positioned upon the pedestal to a third temperature that is higher than the first temperature; and
rounding the plurality of corners of the trench using a sputtering process.

4. The method of claim 1, further comprising:
flowing an oxygen gas into the chamber after stripping the photoresist layer from the insulating layer; and
igniting a plasma within the chamber to remove residues remaining on the insulating layer after the photoresist layer has been stripped.

5. The method of claim 1, wherein the pedestal is an electrostatic chuck, the method further comprising:
clamping the semiconductor wafer onto the pedestal with an electrostatic force, the electrostatic chuck including a resistive heater to raise the temperature of the wafer to the second temperature.

6. The method of claim 5, further comprising:
providing a backside gas between the semiconductor wafer and the pedestal.

7. The method of claim 6, wherein the backside gas includes helium.

8. The method of claim 1, wherein the first temperature is between 100-300° C.

9. The method of claim 8, wherein the second temperature is between 350-450° C. .

10. The method of claim 9, wherein the second temperature is between 350-400° C.

11. The method of claim 1, wherein the volatile species include moisture on or within the patterned insulating layer.

12. A method of stripping photoresist and removing residues from a semiconductor substrate, the method comprising:
placing a semiconductor substrate on a top surface of a pedestal provided within a chamber;
stripping a patterned photoresist layer overlying the substrate within the process chamber in an oxygen containing atmosphere while maintaining a temperature of the substrate at about 300° C. or less, the patterned photoresist layer overlying a patterned insulating layer, the patterned layers defining a trench; and
raising the temperature of the semiconductor substrate provided within the chamber to about 300° C. or more to remove volatile species within the insulating layer.

13. A method of stripping photoresist and removing residues from a semiconductor substrate, the method comprising:
placing a semiconductor substrate on a top surface of a pedestal provided within a chamber;
stripping a photoresist layer overlying the substrate within the process chamber in an oxygen containing atmosphere while maintaining a temperature of the substrate at about 250° C. or less, the photoresist layer defining a trench and overlying an insulating layer that defines a trench;
igniting a plasma from a oxygen-containing gas to remove residues remaining on the insulating layer after the stripping step while maintaining the temperature of the substrate at about 275° C. or less; and
raising the temperature of the semiconductor substrate provided within the chamber to about 300° C. or more to remove volatile species within the insulating layer.

14. A method of stripping photoresist and removing residues from a semiconductor substrate, the method comprising:
placing a semiconductor substrate on a top surface of an electrostatic chuck provided within the chamber;
stripping a patterned photoresist layer overlying the substrate within the process chamber while maintaining a temperature of the substrate at about 300° C. or less, the patterned photoresist layer overlying a patterned insulating layer, the patterned layers defining a trench; and
raising a temperature of the semiconductor substrate provided within the chamber to about 300° C. or more to remove volatile species within the insulating layer, wherein the temperature raising step includes:
applying a voltage to the chuck to clamp the substrate to the chuck using an electrostatic force, and
flowing a backside gas between the substrate and the chuck.

15. The method of claim 14, wherein the chuck includes a heater that maintains the top surface of the chuck at about 400° C. or more.

16. The method of claim 14, further comprising:
flowing an oxygen gas into the chamber after stripping the photoresist layer from the insulating layer; and
thereafter, igniting a plasma within the chamber to remove residues remaining on the insulating layer after the photoresist layer has been stripped.

17. The method of claim 14, wherein residues of oxide and carbon materials remain on or over the substrate after the photoresist layer has been stripped, the method further comprising:
flowing an oxygen-containing gas into the chamber after stripping the photoresist layer from the insulating layer;
igniting a plasma from the oxygen-containing gas within the chamber to remove the carbon residues remaining on or over the substrate;
thereafter, flowing a fluorine-containing gas into the chamber; and
igniting a plasma from the fluorine-containing gas to remove the oxide residues remaining on or over the substrate.

18. The method of claim 17, wherein the patterned insulating layer defines a trench, the method further comprising:
after the volatile species have been removed from the insulating layer, accelerating projectiles to the substrate to round corners of the trench.

19. A method of stripping photoresist and removing residues from a semiconductor wafer, the method comprising:
stripping a patterned photoresist layer overlying a semiconductor substrate in an oxygen containing atmosphere while maintaining the substrate positioned upon a pedestal within a process chamber at a temperature of no more than about 300° C., the patterned photoresist layer overlying a patterned insulating layer, wherein residues of oxide and carbon materials remain on or over the substrate after the photoresist layer has been stripped, wherein the patterned layers define a trench;
providing an oxygen-containing gas into the chamber to ignite a plasma and remove the carbon residues remaining on or over the substrate;
providing a fluorine-containing gas into the chamber to ignite a plasma from the fluorine-containing gas to remove the oxide residues remaining on or over the substrate;
applying a voltage to the chuck to clamp the substrate to the top surface of the chuck using an electrostatic force, the top surface of chuck being no less than about 400° C.;
providing a backside gas between the substrate and the chuck; and
raising and maintaining a temperature of the substrate positioned upon the pedestal at about 350° C. or more for at least 20 seconds to remove volatile species from the insulating layer.

20. A method of stripping photoresist and removing residues from a semiconductor substrate, the method comprising:
providing a semiconductor substrate having a patterned insulating layer overlying the substrate and a patterned photoresist layer overlying the patterned insulating layer, the patterned insulating layer defining a trench;
placing the semiconductor substrate on a top surface of an electrostatic chuck provided within a process chamber;
stripping the photoresist layer provided on the patterned insulating layer within the process chamber while maintaining the substrate at a first temperature of about 300° C. or less; and
thereafter, raising the first temperature of the substrate provided within the chamber to a second temperature of about 350° C. or more to remove a material on or within the insulating layer.

21. A semiconductor process system, comprising:
a housing to form a process chamber;
an electrostatic chuck to hold a semiconductor substrate within the process chamber, the substrate having a patterned insulating layer overlying the substrate and a patterned photoresist layer overlying the patterned insulating layer, the patterned insulating layer and the patterned photoresist layer defining a trench;
a gas distribution system to introduce a process gas into said vacuum chamber;
a plasma generation system to create a plasma from the process gas within the process chamber;
a temperature control system to control the temperature of the semiconductor substrate;
a controller to control the gas distribution system, the plasma generation system, and the temperature control system; and
a memory coupled to the controller and storing a program to direct the operation of the system, the program including a set of instructions to process the substrate by:
controlling the plasma generation system and temperature control system to form a plasma from the process gas to strip a patterned photoresist layer overlying a semiconductor wafer while maintaining the wafer positioned upon a pedestal within a process chamber at a first temperature, the patterned photoresist layer overlying a patterned insulating layer; and
controlling the temperature control system to raise the first temperature of the wafer positioned upon the pedestal within the chamber to a second temperature to remove volatile species from the patterned insulating layer.
